(19) United States
(12) Patent Application Publication
(10) Pub. No.: US 2026/0118708 A1
(43) Pub. Date: Apr. 30, 2026

(54) LIGHT EMITTING APPARATUS AND MODULE HAVING THE SAME

(71) Applicant: SEOUL VIOSYS CO., LTD., Ansan-si (KR)

(72) Inventors: Miso KO, Ansan-si (KR); Eunmi CHOI, Ansan-si (KR)

(73) Assignee: SEOUL VIOSYS CO., LTD., Ansan-si (KR)

(21) Appl. No.: 19/364,742

(22) Filed: Oct. 21, 2025

Related U.S. Application Data
(60) Provisional application No. 63/711,970, filed on Oct. 25, 2024.

(51) Int. Cl. G02F 1/133; G02F 1/1334; H10F 39/95; H10H 29/24; H10H 29/855

(52) U.S. Cl. CPC G02F 1/13312; G02F 1/1334; H10F 39/95; H10H 29/24; H10H 29/855

(57) ABSTRACT

The present disclosure discloses a light emitting apparatus that includes a light transmittance control layer, first and second electrode layers opposite to each other with the light transmittance control layer interposed therebetween and applying a signal to the light transmittance control layer, at least one light emitting device disposed at a side of the first electrode layer or the second electrode layer, and at least one sensor disposed on a surface of at least one of the first and second electrode layers, in which the light emitting device is not vertically overlapped with the sensor.

### TECHNICAL FIELD

The present disclosure relates to a light emitting apparatus and a light emitting module having the same.

### BACKGROUND ART

A light emitting diode (LED) is one of the light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these characteristics, light emitting diodes are rapidly replacing conventional light sources. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current can flow from the p-electrode pad through the semiconductor layers to the n-electrode pad, and light generated through the recombination of electrons and holes in the active layer may be emitted.

### DISCLOSURE

### Technical Problem

The present disclosure is to provide a light emitting apparatus and a light emitting module having the same capable of controlling light transmittance.

The present disclosure is to provide a light emitting apparatus and a light emitting module having the same that accurately adjust light transmittance for each region.

The present disclosure is to provide a light emitting apparatus and a light emitting module having the same in which a plurality of light emitting devices are spaced apart from one another and can be independently controlled, and the apparatus is capable of differentially and independently adjusting light transmittance for each region.

The present disclosure aims to provide a light emitting apparatus and a light emitting module having the same that control a light transmittance of a light transmittance control layer in real time based on an external environmental signal detected by a sensor.

The present disclosure aims to provide a light emitting apparatus and a light emitting module having the same that improve the performance, reliability, and control precision of the apparatus by optimizing the structural arrangement of an electrode layer, a light emitting device, and a sensor.

The present disclosure aims to provide a light emitting apparatus and a light emitting module having the same that allow operations of a light transmittance control layer and a light emitting device to be automatically or dynamically controlled based on a sensing value.

The present disclosure aims to provide a light emitting apparatus and a light emitting module having the same that precisely control, for each region, light transmittance and light emitting characteristics according to various environmental conditions or user input, thereby allowing flexibly response to user needs or environmental changes, and improving visibility and energy efficiency.

### Technical Solution

A light emitting apparatus according to an embodiment of the present disclosure may include a light transmittance control layer, first and second electrode layers opposite to each other with the light transmittance control layer interposed therebetween and applying a signal to the light transmittance control layer, at least one light emitting device disposed at a side of the first electrode layer or the second electrode layer, and at least one sensor disposed on one surface of at least one of the first and second electrode layers.

In an embodiment, the light emitting device may not be vertically overlapped with the sensor.

In an embodiment, the light emitting apparatus may further include a third electrode layer disposed at a side of the light emitting device.

In an embodiment, the first electrode layer may include an electrically conductive protrusion pattern protruding from one surface.

In an embodiment, the sensor may be disposed on the protrusion pattern.

In an embodiment, the sensor may be disposed on a remaining region excluding the protrusion pattern.

In an embodiment, the protrusion pattern may be in a shape of a mesh.

In an embodiment, the protrusion pattern may include one or more linear patterns.

In an embodiment, a light transmittance of the light transmittance control layer may be controlled based on a sensing value detected by the sensor.

In an embodiment, the light emitting device is provided in a plurality, and the plurality of light emitting devices may be spaced apart from one another to be independently controlled.

In an embodiment, the sensor is provided in a plurality, the plurality of sensors is spaced apart from one another, and a light transmittance of each region of the light transmittance control layer may be controlled based on positions of the plurality of sensors and the sensing values detected by the sensors.

In an embodiment, the light emitting device may be disposed at a side of the second electrode layer, and the sensor may be disposed on one surface of the second electrode layer.

In an embodiment, the first electrode layer may include a first region having a first thickness and a second region having a second thickness smaller than the first thickness, and the second region may be vertically overlapped with the light emitting device.

In an embodiment, the light emitting apparatus may further include a light-transmissive cover disposed on a first electrode layer side or a second electrode layer side and having a light exiting surface.

In an embodiment, the light-transmissive cover may further include an adhesive layer for securing the light-transmissive cover to the first electrode layer side or the second electrode layer side.

A light emitting apparatus according to an embodiment of the present disclosure may include a first light transmittance control layer, first and second electrode layers opposite to each other with the first light transmittance control layer interposed therebetween and applying a signal to the light transmittance control layer, at least one light emitting device disposed at a side of the first electrode layer or the second electrode layer, a second light transmittance control layer opposite to the first light transmittance control layer with the light emitting device interposed between the first and second light transmittance control layers, and third and fourth electrode layers opposite to each other with the second light transmittance control layer interposed therebetween and applying a signal to the second light transmittance control layer.

In an embodiment, the light emitting apparatus may include at least one sensor disposed on at least one surface of the first through fourth electrode layers.

In an embodiment, a light transmittance of the first or second light transmittance control layer may be controlled based on a sensing value detected by the sensor.

In an embodiment, the light emitting device may be disposed between the second electrode layer and the third electrode layer, and may be electrically connected to at least one of the second electrode layer and the third electrode layer.

In an embodiment, the sensor is provided in a plurality, and at least one of the plurality of sensors may be a first sensor disposed in the first or second electrode layer, and at least one of the plurality of sensors may be a second sensor disposed in the third or fourth electrode layer.

In an embodiment, the light emitting device may be disposed between the second electrode layer and the third electrode layer, the first sensor may be disposed in the second electrode layer, and the second sensor may be disposed in the third electrode layer.

In an embodiment, the light transmittance of the first light transmittance control layer may be controlled based on a sensing value detected by the first sensor, and the light transmittance of the second light transmittance control layer may be controlled based on a sensing value detected by the second sensor.

In an embodiment, the light transmittance of the first light transmittance control layer and the light transmittance of the second light transmittance control layer may be controlled independently of each other.

### Advantageous Effect

The present disclosure can provide a light emitting apparatus and a light emitting module having the same capable of controlling light transmittance.

The present disclosure can provide a light emitting apparatus and a light emitting module having the same that accurately adjust light transmittance for each region.

The present disclosure can provide a light emitting apparatus and a light emitting module having the same in which a plurality of light emitting devices are spaced apart from one another, and can be independently controlled, and the apparatus is capable of differentially and independently adjusting light transmittance for each region.

The present disclosure can provide a light emitting apparatus and a light emitting module having the same that control a light transmittance of a light transmittance control layer in real time based on an external environmental signal detected by a sensor.

The present disclosure can provide a light emitting apparatus and a light emitting module having the same that improve the performance, reliability, and control precision of the apparatus by optimizing the structural arrangement of an electrode layer, a light emitting device, and a sensor.

The present disclosure can provide a light emitting apparatus and a light emitting module having the same that allow operations of a light transmittance control layer and a light emitting device to be automatically or dynamically controlled based on a sensing value.

### BRIEF DESCRIPTION OF DRAWING

FIG. 1A and FIG. 1B are cross-sectional views illustrating a light emitting apparatus according to an embodiment of the present disclosure.

FIG. 2 is a plan view illustrating an electrode layer and a sensor of the light emitting apparatus of FIGS. 1A and 1B.

FIG. 3 is a modified example of FIG. 2.

FIG. 4 is a cross-sectional view illustrating a light emitting apparatus according to another embodiment of the present disclosure.

FIG. 5 is a plan view illustrating an electrode layer and a sensor of FIG. 4.

FIG. 6 is a cross-sectional view in a direction of I-I′ of FIG. 5.

FIG. 7 is a modified example of FIG. 5.

FIG. 8 is a cross-sectional view in a direction of II-II′ of FIG. 7.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, or others, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus of the present disclosure and a light emitting module having the same will be described in detail through accompanying drawings.

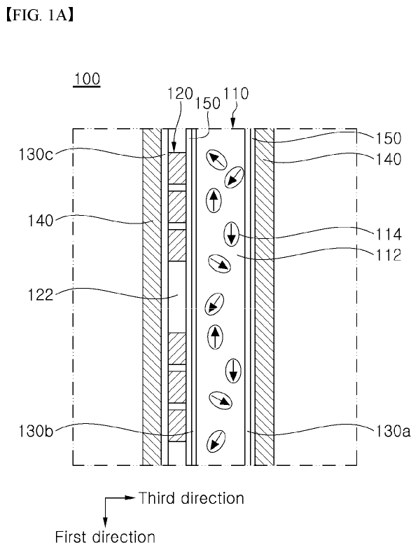

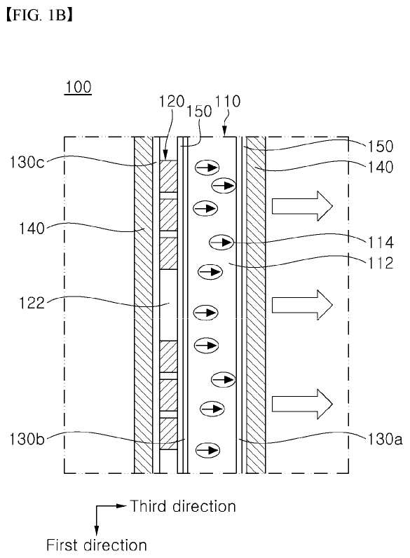

Referring to FIGS. 1A and 1B, a light emitting apparatus 100 of the present disclosure may include a light transmittance control layer 110, first and second electrode layers 130a and 130b opposite to each other with the light transmittance control layer 110 interposed therebetween and applying a signal to the light transmittance control layer 110, and at least one light emitting device 120 disposed at a side of the first electrode layer 130a or the second electrode layer 130b.

The light transmittance control layer 110 is configured to vary a light transmittance of the light emitting apparatus 100, and various configurations are possible. The light transmittance control layer 110 is disposed between the first electrode layer 130a and the second electrode layer 130b, and light transmittance characteristics may be varied depending on the signal applied by the first electrode layer 130a and the second electrode layer 130b. The signal may be at least one of an electrical signal, an electrostatic signal, or a physical signal. The light transmittance control layer 110 may include at least one of a liquid crystal material, particles, film, or filter for varying the light transmittance characteristics.

As an example, the light transmittance control layer 110 may be a polymer dispersed liquid crystal (PDLC) film. The light transmittance control layer 110 may include a polymer matrix 112 and a plurality of liquid crystal droplets 114 dispersed within the polymer matrix 112.

The polymer matrix 112 may stably support the liquid crystal droplets 114 and secure mechanical strength.

The liquid crystal droplets 114 may be evenly distributed within the polymer matrix 112.

FIG. 1A shows a distribution of liquid crystal droplets 114 in a state that no voltage is applied to the first and second electrode layers 130a and 130b, in which liquid crystal molecules in each liquid crystal droplet 114 are arranged in a disorderly and irregular manner and may scatter incident light. As a result, the light transmittance control layer 150 has a low light transmittance state, and may be an opaque layer.

On the other hand, FIG. 1B shows a distribution of liquid crystal droplets 114 in a state that voltage is applied to the first and second electrode layers 130a and 130b, and when voltage is applied to the electrode layers 130a and 130b, liquid crystal molecules in the liquid crystal droplets 114 are arranged in a direction of an electric field, so that incident light may travel in a straight line. As a result, the light transmittance control layer 150 has a high light transmittance state, and may be a transparent layer.

As described above, the light transmittance control layer 110 may have its light transmittance characteristics varied in real time according to the electric field applied from the outside by the first and second electrode layers 130a and 130b.

The light transmittance control layer 110 is capable of controlling light transmittance, thereby simplifying a structure thereof and improving transparency.

The first electrode layer 130a is an electrode layer disposed at a side of the light transmittance control layer 110, and may apply a signal to the light transmittance control layer 110 and have high transmittance to light.

For example, the first electrode layer 130a may be a transparent conductive film. The first electrode layer 130a may transmit light while allowing current to flow stably.

The first electrode layer 130a includes Indium Tin Oxide (ITO), Fluorine-doped Tin Oxide (FTO), metal nanowires, graphene, carbon nanofibers (CNT), or others, and may provide high light transmittance and electrical conductivity.

The first electrode layer 130a may be formed by depositing or patterning a transparent conductive material on a transparent base substrate such as glass or plastic.

The second electrode layer 130b may be an opposing electrode layer opposite to the first electrode layer 130a with the light transmittance control layer 110 interposed therebetween. The second electrode layer 130b may be configured identically or similarly to the first electrode layer 130a.

The first electrode layer 130a and the second electrode layer 130b may be disposed parallel to each other. Accordingly, an electric field may be distributed parallel and uniformly in the light transmittance control layer 110. In addition, the transparent conductive material of the first electrode layer 130a and the second electrode layer 130b may be configured through micro-patterning to selectively apply the electric field only to a particular region.

The light emitting device 120 may be disposed on a side of the first electrode layer 130a or the second electrode layer 130b. FIG. 1A and FIG. 1B illustrate an example in which the light emitting device 120 is disposed on a second electrode layer 130b side, but the present disclosure is not limited thereto.

As the light emitting device 120 is disposed on the second electrode layer 130b side, the second electrode layer 130b may be disposed between the light emitting device 120 and the light transmittance control layer 110. A transparent adhesive layer 150 may be disposed between the light emitting device 120 and the second electrode layer 130b. The transparent adhesive layer 150 is an optional configuration and may be omitted.

The light emitting device 120 may be provided in a plurality, and may be disposed in various shapes. A plurality of light emitting devices 120 may be spaced apart from one another.

The light emitting device 120 may be electrically connected to the second electrode layer 130b. In this case, a conductive pattern for the light emitting device 120 may be formed on one surface of the second electrode layer 130b facing the light emitting device 120.

The light emitting devices 120 may be controlled independently of one another.

The light emitting device 120 may be, for example, a light emitting diode. For example, the light emitting device 120 may include a first conductivity type semiconductor layer, a second conductivity type semiconductor layer, and an active layer disposed between the first conductivity type semiconductor layer and the second conductivity type semiconductor layer.

The first conductivity type semiconductor layer may include a phosphide or nitride semiconductor such as (Al, Ga, In)P or (Al, Ga, In)N, and may be disposed on a support substrate using a method such as MOCVD, MBE, HVPE, or the like.

The support substrate may include a heterogeneous substrate such as a sapphire substrate, a gallium arsenide substrate, a silicon substrate, a silicon carbide substrate, or a spinel substrate, and may also include a homogeneous substrate such as a gallium nitride substrate, an aluminum nitride substrate, or the like. The support substrate may be removed later.

The first conductivity type semiconductor layer may be doped as n-type by including one or more impurities such as Si, C, Ge, Sn, Te, Pb, or others. However, without being limited thereto, the first conductivity type semiconductor layer may be doped with an opposite conductivity type, including a p-type dopant.

The active layer may be a light emitting layer disposed on a side of the first conductivity type semiconductor layer. The active layer is a light emitting layer formed on a side of the first conductivity type semiconductor layer, and may include a phosphide or nitride semiconductor such as (Al, Ga, In)P or (Al, Ga, In)N, and may be grown on the first conductivity type semiconductor layer using a technique such as MOCVD, MBE, HVPE, or the like. In addition, the active layer may include a quantum well structure (QW) including at least two barrier layers and at least one well layer, and further may include a multi-quantum well structure (MQW) including a plurality of barrier layers and a plurality of well layers. A wavelength of light emitted from the active layer may be adjusted by controlling a composition ratio of materials forming the well layer.

The second conductivity type semiconductor layer may be a semiconductor layer disposed on a side of the active layer. The second conductivity type semiconductor layer may include a phosphide or nitride semiconductor such as (Al, Ga, In)P or (Al, Ga, In)N, and may be grown using a technique such as MOCVD, MBE, HVPE, or the like. The second conductivity type semiconductor layer may be doped with a conductivity type opposite to that of the first conductivity type semiconductor layer. For example, the second conductivity type semiconductor layer may be doped as p-type by including an impurity such as Mg.

The light emitting device 120 may include a first electrode electrically connected to the first conductivity type semiconductor layer and a second electrode electrically connected to the second conductivity type semiconductor layer.

For example, the first electrode and the second electrode may be connected to the conductive pattern of the second electrode layer 130b. In a case that the light emitting device 120 is disposed on a first electrode layer 130a side, the first electrode and the second electrode may be connected to a conductive pattern of the first electrode layer 130a.

The light emitting devices 120 may emit similar colors to one another. Alternatively, at least one of the light emitting devices 120 may emit light having a peak wavelength different from that of the other light emitting devices 120.

In addition, the light emitting device 120 may further include a wavelength conversion layer. Light generated in the active layer of the light emitting device 120 may be excited and wavelength-converted in the wavelength conversion layer and emitted.

Meanwhile, referring back to FIG. 1A, the light emitting apparatus 100 may further include a third electrode layer 130c disposed at a side of the light emitting device 120. The light emitting device 120 may be disposed between the second electrode layer 130b and the third electrode layer 130c. Alternatively, in the case that the light emitting device 120 is disposed on the first electrode layer 130a side, the light emitting device 120 may be disposed between the first electrode layer 130a and the third electrode layer 130c. Therefore, an intensity of light emitted through the third electrode layer 130c may be adjusted to be different from that of light emitted through the light transmittance control layer 110, thereby adjusting a luminous intensity according to a light emitting direction.

As an example, the third electrode layer 130c may be configured identically or similarly to the first and second electrode layers 130a and 130b.

As another example, the third electrode layer 130c may include a base substrate and a conductive pattern formed on one surface of the base substrate.

The base substrate may be a circuit board, a light-transmitting substrate, a glass substrate, a TFT substrate, a polymer substrate, a flexible substrate, a polyimide substrate, or the like.

The conductive pattern may be a transparent electrode. The conductive pattern may be disposed within the base substrate or may pass through the base substrate.

The conductive pattern of the third electrode layer 130c may be electrically connected to the light emitting devices 120. The second electrode layer 130b and the third electrode layer 130c may be spaced apart by the light emitting device 120. A region between the second electrode layer 130b and the third electrode layer 130c may be a light emitting region.

A space 122 between the light emitting devices 120 in the light emitting region may be filled with a light-transmitting material, or may be filled with air.

As an optional configuration, the light emitting apparatus 100 may further include a light-transmissive cover 140 for supporting and protecting the light emitting device 120 and the light transmittance control layer 110 from the outside. The light-transmissive cover 140 may be provided with a light exiting surface. The cover 140 may be formed of a transparent material such as glass or the like.

The cover 140 may not only function as a support, but also protect internal light emitting device 120 and light transmittance control layer 110 from external impacts or scratches, and block external environments such as external moisture, oxygen, and temperature changes, and others, thereby improving a stability of operation and lifespan thereof.

FIG. 1A and FIG. 1B illustrate an example in which the covers 140 are provided on both sides with the light emitting device 120 and the light transmittance control layer 110 in between, but it is also possible to install the cover 140 only on one side, and an example in which the cover 140 is omitted entirely is also possible.

The light-transmissive cover 140 may be disposed on the first electrode layer 130a side or a second electrode layer 130b side, and in this case, the light emitting apparatus 100 may further include the transparent adhesive layer 150 for securing the light-transmissive cover 140 on the first electrode layer side or the second electrode layer side.

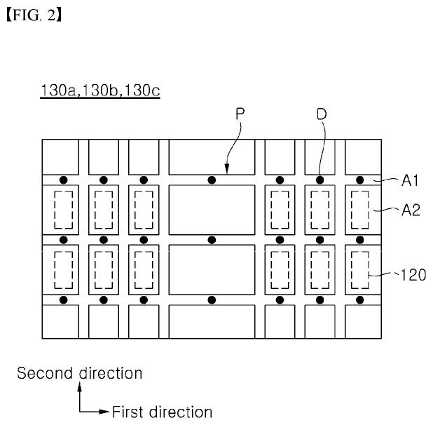

Meanwhile, FIG. 2 illustrates the first through third electrode layers 130a, 130b, and 130c of FIG. 1A and FIG. 1B, and the first through third electrode layers 130a, 130b, and 130c may further include an electrically conductive protrusion pattern P protruding from one surface.

The electrically conductive protrusion pattern P may be provided on at least one of the first through third electrode layers 130a, 130b, and 130c. For example, the electrically conductive protrusion pattern P may be provided on the first electrode layer 130a. Hereinafter, it will be exemplarily described that the electrically conductive protrusion pattern P is formed on the first electrode layer 130a, but it is also possible that the electrically conductive protrusion pattern P is formed on the second or third electrode layer 130b or 130c.

The electrically conductive protrusion pattern P is a protrusion protruding from one surface of the first electrode layer 130a, and may form a first region A1 having a thickness that is larger than those of other regions. Remaining regions excluding the first region A1 may form a second region A2 that is thinner than the first region A1. When the first region A1 has a first thickness and the second region A2 has a second thickness, the second thickness may be smaller than the first thickness.

The first region A1 may be a region where a conductive material is formed on the transparent base substrate of the first electrode layer 130a. Alternatively, the first region A1 may be a region in which the conductive material is formed thicker than the second region A2. As formation thicknesses of the conductive materials are different in the first region A1 and the second region A2, the first region A1 may have electrical characteristics (resistance, electrical conductivity, or others) different from those of the second region A2, and as a result, it may have a light transmittance different from that of the second region A2 when a signal is applied from the outside. Accordingly, a light transmittance of each region may be precisely and accurately adjusted.

The electrically conductive protrusion pattern P may include one or more linear patterns.

For example, the protrusion pattern P may be in a shape of a mesh. Accordingly, the first region A1 may be formed in a plurality of linear shapes, some of the plurality of lines may extend in a first direction, and some of the lines may extend in a second direction perpendicular to the first direction. The first region A1 may form a plurality of intersections. The second region A2 may be surrounded by the first region A1. The first region A1 may be in the shape of the mesh, but this is merely exemplary and the present disclosure is not limited thereto.

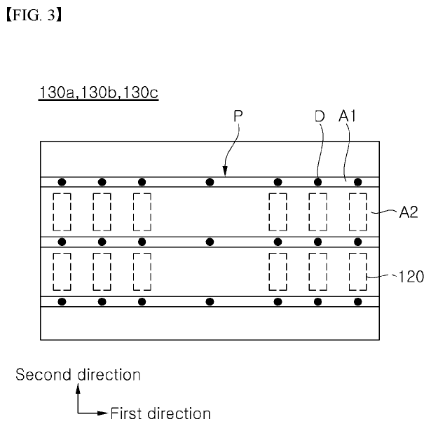

FIG. 3 is a modified example of FIG. 2, in which the first region A1 may be formed as a plurality of linear shapes extending in the first direction, and the plurality of lines may be spaced apart along the second direction.

In addition, the first region A1 may be a region that is not vertically overlapped with the light emitting device 120. The first region A1 may be a region extending between the light emitting devices 120. In this case, the second region A2 may be vertically overlapped with the light emitting device 120.

Alternatively, the first region A1 may be a region that is vertically overlapped with the light emitting device 120. The first region A1 may extend along an arrangement direction of the light emitting device 120 at a position that is vertically overlapped with the light emitting device 120.

Referring back to FIG. 2, the light emitting apparatus 100 may include at least one sensor D.

The sensor D may be a contact sensor or a non-contact sensor. The sensor D may be a sensor capable of detecting an external environment, contact, position, distance, and others in a contact or non-contact manner. Alternatively, the sensor D may be a sensor capable of detecting a force applied from the outside. Alternatively, the sensor D may be a sensor capable of detecting temperature, light, sound, and others.

For example, the sensor D may be a piezoelectric sensor, an electrostatic sensor, an illumination sensor, a position sensor, a distance sensor, or a touch sensor, but this is merely exemplary and the present disclosure is not limited thereto.

The sensor D may be provided in a plurality. The plurality of sensors D may be spaced apart from one another. At least one of the plurality of sensors D may be a sensor that detects a different type of physical quantity than those of the other sensors D.

The sensor D may be disposed on at least one surface of the first and second electrode layers 130a and 130b. In a case that the light emitting apparatus 100 further includes the third electrode layer 130c, the sensor D may be disposed on at least one surface of the first through third electrode layers 130a, 130b, and 130c.

For example, the sensor D may be disposed on one surface of the first electrode layer 130a. Hereinafter, it will be exemplarily described that the sensor D is disposed on the first electrode layer 130a, but the present disclosure is not limited thereto, and an example in which the sensor D is disposed on the second or third electrode layer 130b or 130c is also possible.

As illustrated in FIG. 2, the sensor D may be disposed on the electrically conductive protrusion pattern P. That is, the sensor D may be disposed within the first region A1. The sensor D may be electrically connected through the protrusion pattern P, and accordingly, a more stable electrical connection may be possible.

Alternatively, as illustrated in FIG. 3, the sensor D may be disposed on a remaining region excluding the protrusion pattern P. That is, the sensor D may be disposed within the second region A2. In this case, the sensor D may be surrounded by the first region A1. Therefore, as the sensor D is disposed in the second region A2 having a relatively smaller thickness, a height difference between an upper surface of the sensor D and the first region A1 may be reduced.

In this case, the light emitting device 120 may not be vertically overlapped with the sensor D. The sensor D may be disposed in a position where it is not vertically overlapped with the light emitting device 120. That is, the sensor D may be disposed between adjacent light emitting devices 120. Accordingly, it is possible to prevent a situation in which the sensor D blocks light emitted from the light emitting device 120 to reduce radiation efficiency.

In addition, since the sensor D is spaced apart from the light emitting device 120 in a vertical direction, interference of light emitted from the light emitting device 120 may be prevented.

Meanwhile, referring again to FIG. 1A, in a case that the sensor D is disposed on one surface of the second electrode layer 130b, the sensor D may be covered by the light transmittance control layer 110 and the light emitting region of the light emitting device 120. Accordingly, the sensor D may be prevented from being damaged by external factors.

Referring again to FIGS. 1A and 1B, a light transmittance of the light transmittance control layer 110 may be controlled based on a sensing value detected by the sensor D.

Depending on the sensing value detected by the sensor D, a degree of scattering or transmission of the light transmittance control layer 110 may be controlled, and as a result, a light transmittance state of the light emitting apparatus 100 may be varied in real time.

By dynamically changing optical characteristics of the light emitting apparatus 100 through the light transmittance control layer 110, energy efficiency, user convenience, and visibility may be improved. Depending on a light transmittance control of the light transmittance control layer 110, light emitted from the light emitting device 120 may pass through the light transmittance control layer 110 to the outside, may be partially blocked, or may be completely blocked.

In addition, a light transmittance of each region of the light transmittance control layer 110 may be controlled based on positions of the plurality of sensors D and the sensing values detected by the sensors D.

Since the plurality of the sensors D is provided and each sensor D operates independently so that a different sensing value may be detected for each region, the light transmittance of the light transmittance control layer 110 may be controlled by additionally considering the positions of the sensors D. In this case, the light transmittance of the light transmittance control layer 110 may also be controlled differently for each region.

In addition, operations (on/off, intensity, brightness, color, and others) of the light emitting devices 120 may also be controlled based on the sensing value detected by the sensor D. The operations of the light emitting devices 120 may be controlled independently of one another.

As a result, the present disclosure enables each region of the light transmittance control layer 110 to be independently controlled by the plurality of sensors 140, thereby individually controlling the light transmittance for each of multiple regions. In this way, light transmission characteristics of the light emitting apparatus 100 may be customized according to various external signals such as changes in illumination, touch, distance, and others.

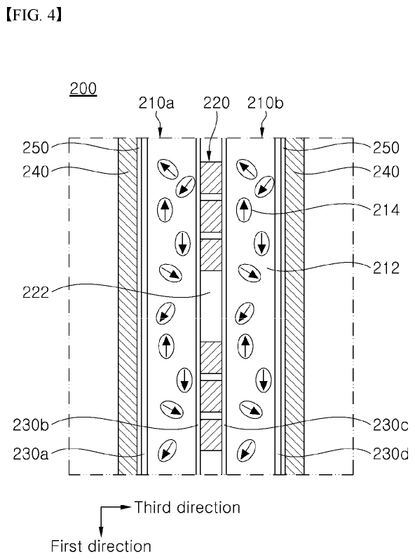

FIG. 4 illustrates a light emitting apparatus 200 according to another embodiment of the present disclosure, which may be configured identically or similarly to the light emitting apparatus 100 of FIGS. 1A through 3, except that it includes two light transmittance control layers 210a and 210b. Hereinafter, the light emitting apparatus 200 of FIG. 4 will be described in detail, focusing on differences from the light emitting apparatus 100 of FIGS. 1A through 3.

The light emitting apparatus 200 may include a first light transmittance control layer 210a, first and second electrode layers 230a and 230b opposite to each other with the first light transmittance control layer 210a interposed therebetween and applying a signal to the first light transmittance control layer 210a, at least one light emitting device 220 disposed on a side of the first electrode layer 230a or the second electrode layer 230b, a second light transmittance control layer 210b opposite to the first light transmittance control layer 210a with the light emitting device 220 interposed therebetween, and third and fourth electrode layers 230c and 230d opposite to each other with the second light transmittance control layer 210b interposed therebetween and applying a signal to the second light transmittance control layer 210b.

The first and second light transmittance control layers 210a and 210b may be configured identically or similarly to the light transmittance control layer 110 of FIGS. 1A and 1A. The first through fourth electrode layers 230a, 230b, 230c, and 230d may be configured identically or similarly to the first through third electrode layers 130a, 130b, and 130c of FIGS. 1A through 3.

A signal may be applied to the first light transmittance control layer 210a through the first and second electrode layers 230a and 230b, and a light transmittance thereof may be controlled by the applied signal. Likewise, a signal may be applied to the second light transmittance control layer 210b through the third and fourth electrode layers 230c and 230d, and a light transmittance thereof may be controlled by the applied signal.

Light transmittances of the first light transmittance control layer 210a and the second light transmittance control layer 210b may be controlled independently of each other.

The light emitting device 220 may be configured identically or similarly to the light emitting device 120 of FIGS. 1A and 1B.

The light emitting device 220 may be disposed between the second electrode layer 230b and the third electrode layer 230c. The light emitting device 220 may be electrically connected to at least one of the second electrode layer 230b and the third electrode layer 230c. For example, the light emitting device 220 may be electrically connected to the second electrode layer 230b and the third electrode layer 230c.

The sensor D may be disposed on at least one surface of the first through fourth electrode layers 230a, 230b, 230c, and 230d. In a case that the sensor D is disposed on the second or third electrode layer 230b or 230c, the sensor D may be covered by the first or second light transmittance control layer 210a or 210b. Accordingly, the sensor D may be prevented from being damaged by external factors. In addition, it is possible to prevent the sensor D from being visible from the outside.

The light transmittance of the first or second light transmittance control layer 210a or 210b may be controlled based on a sensing value detected by the sensor D.

In more detail, the light emitting apparatus 200 may include a plurality of sensors D.

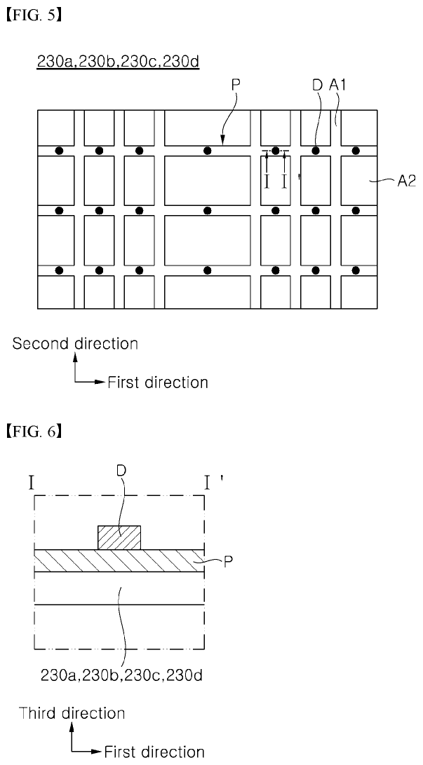

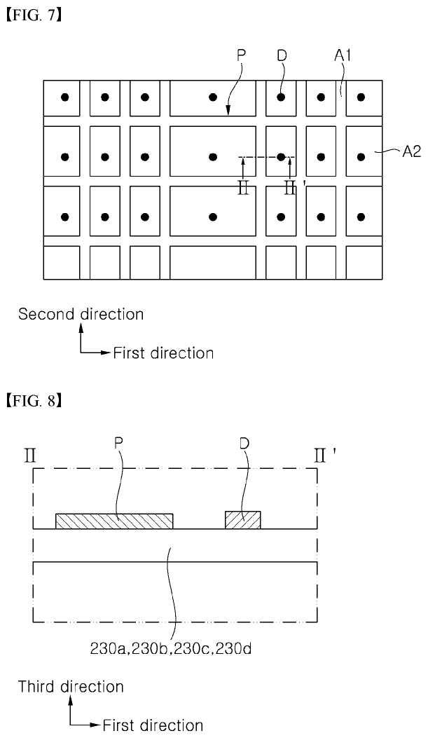

The sensor D, as illustrated in FIG. 5, may be disposed on a protrusion pattern P of the electrode layer 230a, 230b, 230c, and 230d, that is, within a first region A1, or as illustrated in FIG. 7, may be disposed in a region excluding a protrusion pattern P, that is, within a second region A2.

The FIG. 6 shows a form in which the sensor D is disposed within the first region A1, and FIG. 8 shows a form in which the sensor D is disposed within the second region A2. In a case that the sensor D is disposed within the second region A2, a height difference between an upper surface of the sensor D and an upper surface of the protrusion pattern P may be reduced, thereby reducing a step in the electrode layers 230a, 230b, 230c, and 230d.

Meanwhile, at least one of the plurality of sensors D may be a first sensor disposed on the first or second electrode layer 230a or 230b.

The first sensor may be provided in a plurality. The light transmittance of the first light transmittance control layer 210a may be controlled based on a sensing value detected by the first sensor.

At least one of the plurality of sensors D may be a second sensor disposed on the third or fourth electrode layer 230c or 230d.

The second sensor may be provided in a plurality. The light transmittance of the second light transmittance control layer 210b may be controlled based on a sensing value detected by the second sensor.

As an example, the first sensor may be disposed on the second electrode layer 230b, and the second sensor may be disposed on the third electrode layer 230c.

Since the light transmittance of the first light transmittance control layer 210a is controlled based on the sensing value detected by the first sensor and the light transmittance of the second light transmittance control layer 210b is controlled based on the sensing value detected by the second sensor, the light transmittance of the first light transmittance control layer 210a and the light transmittance of the second light transmittance control layer 210b may be controlled differently from each other.

That is, the light transmittance of the first light transmittance control layer 210a and the light transmittance of the second light transmittance control layer 210b may be controlled independently of each other.

Meanwhile, the light emitting apparatuses 100 and 200 may be applied to various light emitting modules. For example, the light emitting module may be a smart window, lighting, sensor-integrated user interface (touch), vehicle glass, privacy glass, advertising panel, or others that are capable of automatically controlling transparency and adjusting an amount of light transmitted according to external illuminance.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200: Light emitting apparatus
110, 210a, 210b: Light transmittance control layer
120, 220: Light emitting device
130a, 130b, 130c, 230a, 230b, 230c, 230d: Electrode layer
140, 240: Light-transmissive cover
150, 250: Adhesive layer
112, 212: Polymer matrix
114, 214: Liquid crystal droplet

1. A light emitting apparatus, comprising:
a light transmittance control layer;
a first electrode layer;
a second electrode layer, the first and second electrode layers disposed opposite to each other with the light transmittance control layer interposed therebetween and configured to apply a signal to the light transmittance control layer;
at least one light emitting device disposed at a side of the first electrode layer or the second electrode layer; and
at least one sensor disposed on a surface of at least one of the first or second electrode layers,
wherein the at least one light emitting device is not vertically overlapped with the at least one sensor.

2. The light emitting apparatus of claim 1, further comprising:
a third electrode layer disposed at a side of the at least one light emitting device.

3. The light emitting apparatus of claim 1,
wherein the first electrode layer includes an electrically conductive protrusion pattern protruding from the surface.

4. The light emitting apparatus of claim 3,
wherein the sensor is disposed on the electrically conductive protrusion pattern.

5. The light emitting apparatus of claim 3,
wherein the sensor is disposed on a remaining region excluding the electrically conductive protrusion pattern.

6. The light emitting apparatus of claim 3,
wherein the electrically conductive protrusion pattern is in a shape of a mesh.

7. The light emitting apparatus of claim 3,
wherein the electrically conductive protrusion pattern includes one or more linear patterns.

8. The light emitting apparatus of claim 1,
wherein a light transmittance of the light transmittance control layer is controlled based on a sensing value detected by the at least one sensor.

9. The light emitting apparatus of claim 1, wherein:
the at least one light emitting device is provided in a plurality of light emitting devices, and
each of the plurality of light emitting devices is spaced apart from one another and controlled independently.

10. The light emitting apparatus of claim 1, wherein:
the at least one sensor is provided in a plurality of sensors,
each of the plurality of sensors is spaced apart from one another, and
a light transmittance of each region of the light transmittance control layer is controlled based on positions of the plurality of sensors and sensing values detected by the plurality of sensors.

11. The light emitting apparatus of claim 2, wherein:
the at least one light emitting device is disposed on a side of the second electrode layer, and
the at least one sensor is disposed on a surface of the second electrode layer.

12. The light emitting apparatus of claim 1,
wherein the first electrode layer includes a first region having a first thickness and a second region having a second thickness smaller than the first thickness, and the second region is vertically overlapped with the at least one light emitting device.

13. The light emitting apparatus of claim 1, further comprising:
a light-transmissive cover disposed on a first electrode layer side or a second electrode layer side and having a light exiting surface.

14. The light emitting apparatus of claim 13, further comprising:
an adhesive layer for securing the light-transmissive cover to the first electrode layer side or the second electrode layer side.

15. A light emitting apparatus, comprising:
a first light transmittance control layer;
a first electrode layer;
a second electrode layer, the first and second electrode layers disposed opposite to each other with the first light transmittance control layer interposed therebetween and configured to apply a signal to the first light transmittance control layer;
at least one light emitting device disposed at a side of the first electrode layer or the second electrode layer;
a second light transmittance control layer opposite to the first light transmittance control layer with the at least one light emitting device interposed between the first and second light transmittance control layers;
a third electrode layer;
a fourth electrode layer, the third and fourth electrode layers disposed opposite to each other with the second light transmittance control layer interposed therebetween and configured to apply a signal to the second light transmittance control layer; and
at least one sensor disposed on a surface of at least one of the first, second, third or fourth electrode layers,
wherein a light transmittance of the first or second light transmittance control layer is controlled based on a sensing value detected by the at least one sensor.

16. The light emitting apparatus of claim 15,
wherein the at least one light emitting device is disposed between the second electrode layer and the third electrode layer, and electrically connected to at least one of the second electrode layer and the third electrode layer.

17. The light emitting apparatus of claim 15, wherein:
the at least one sensor is provided in a plurality of sensors,
at least one of the plurality of sensors is a first sensor disposed on the first or second electrode layer, and
at least one of the plurality of sensors is a second sensor disposed on the third or fourth electrode layer.

18. The light emitting apparatus of claim 17, wherein:
the at least one light emitting device is disposed between the second electrode layer and the third electrode layer,
the first sensor is disposed on the second electrode layer, and
the second sensor is disposed on the third electrode layer.

19. The light emitting apparatus of claim 17, wherein:
the light transmittance of the first light transmittance control layer is controlled based on a sensing value detected by the first sensor, and
the light transmittance of the second light transmittance control layer is controlled based on a sensing value detected by the second sensor.

20. The light emitting apparatus of claim 15,
wherein the light transmittance of the first light transmittance control layer and the light transmittance of the second light transmittance control layer are controlled independently of each other.
